(19) United States
(12) Patent Application Publication
(10) Pub. No.: US 2014/0030444 A1
(43) Pub. Date: Jan. 30, 2014

(54) HIGH PRESSURE, HIGH POWER PLASMA ACTIVATED CONFORMAL FILM DEPOSITION

(71) Applicant: Novellus Systems, Inc., Fremont, CA (US)

(72) Inventors: Shankar Swaminathan, Hillsboro, OR (US); Frank Pasquale, Tualatin, OR (US); Adrien Lavoie, Tualatin, OR (US); Karl Leeser, West Linn, OR (US)

(73) Assignee: Novellus Systems, Inc., Fremont, CA (US)

(21) Appl. No.: 13/953,616

(22) Filed: Jul. 29, 2013

Related U.S. Application Data
(60) Provisional application No. 61/677,393, filed on Jul. 30, 2012.

(51) Int. Cl. C23C 16/48

(52) U.S. Cl. CPC C23C 16/48
USPC 427/569; 118/723 I

(57) ABSTRACT

Methods and apparatus for depositing a film on a substrate surface including plasma assisted surface mediated reactions in which a film is grown over one or more cycles of reactant adsorption and reaction are provided. The embodiments disclosed herein relate to methods and apparatus for performing conformal film deposition and atomic layer deposition reactions that result in highly uniform films with low particle contamination. According to various embodiments, the methods and apparatus involve high deposition chamber pressures and plasma generation using high radio frequency powers.

### CROSS REFERENCE TO RELATED APPLICATION

This application claims benefit of U.S. provisional patent application No. 61/677,393, filed Jul. 30, 2012, and titled “HIGH PRESSURE, HIGH POWER PLASMA ACTIVATED CONFORMAL FILM DEPOSITION,” which is incorporated by reference herein in its entirety and for all purposes.

### BACKGROUND

Various thin film layers for semiconductor devices may be deposited with atomic layer deposition (ALD) processes. Under some conditions, some ALD processes may be unable to saturate the wafer, leading to incomplete film deposition on the wafer, film islanding, and film thickness variation. Some approaches to address incomplete film deposition may include longer dosing times to saturate the wafer surface with film precursor. However, extended dosing time may waste valuable precursor during film nucleation phases. The additive effect of extending processing time may diminish process tool throughput, requiring the installation and maintenance of additional process tools to support a production line. Further, films produced by such approaches may have physical, chemical, or electrical characteristics that provide inadequate device performance.

### SUMMARY

Methods and apparatus for depositing a film on a substrate surface are described herein. The methods may involve plasma-driven surface-mediated reactions between reactants. Certain embodiments utilize high chamber pressure and/or high radio frequency (RF) power during plasma exposure to achieve improved film results such as highly uniform films deposited at low cycle times for high throughput.

In one aspect of the disclosed embodiments, a method of depositing a film on a substrate surface in a single or multi-station reaction chamber is provided. The method may include (a) introducing a first reactant in vapor phase into the reaction chamber under conditions allowing the first reactant to adsorb onto the substrate surface; (b) introducing a second reactant in vapor phase into the reaction chamber under conditions allowing the second reactant to adsorb onto the substrate surface; and (c) periodically exposing the substrate surface to plasma when the vapor phase flow of the first reactant has ceased in order to drive a surface reaction between the first and second reactants on the substrate surface to form the film, where an RF power used to drive formation of the plasma is greater than about 1.1 Watts per station per square centimeter of substrate area, and where a pressure in the reaction chamber during operations (a)-(c) is greater than 4 Torr.

The method may also include purging the reaction chamber immediately before exposing the substrate surface to plasma. Similarly, the method may include purging the reaction chamber immediately after exposing the substrate surface to plasma. In some embodiments, the RF power used to drive formation of the plasma is greater than about 1.4 Watts per station per square centimeter of substrate area. For example, in some cases the RF power is between about 1.4-4.2 Watts per station per square centimeter of substrate area.

In certain embodiments, the pressure in the reaction chamber is less than about 20 Torr. For instance, in some cases the pressure in the reaction chamber is between about 5-10 Torr.

The methods may be utilized to deposit a wide variety of film types from a wider variety of reactants. In some cases, the first reactant is a silicon-containing reactant. The second reactant may be an oxygen-containing reactant. In other cases the second reactant may be a nitrogen-containing reactant. Where a silicon-containing reactant is used, it may be introduced into the reaction chamber during a pulse having a duration of less than about 75 milliseconds (ms), or less than about 50 ms. In certain other cases, the first reactant may be a metal-containing reactant. The second reactant may be an oxygen-containing reactant and/or a nitrogen-containing reactant. In some embodiments, the plasma is exposed to the substrate surface in operation (d) for a period of less than about 250 ms.

In various embodiments, the film formed on the substrate has a within wafer non-uniformity of less than about 1.5%. In some cases, for instance, the within wafer non-uniformity is less than about 0.5%.

In another aspect of the disclosed embodiments, a method of depositing a film on a substrate surface is provided. The method may include (a) introducing a first reactant in vapor phase into the reaction chamber under conditions allowing the first reactant to adsorb onto the substrate surface; (b) introducing a second reactant in vapor phase into the reaction chamber under conditions allowing the second reactant to adsorb onto the substrate surface; and (c) periodically exposing the substrate surface to plasma when the vapor phase flow of the first reactant has ceased in order to drive a surface reaction between the first and second reactants on the substrate surface to form the film, where a pressure in the reaction chamber during operations (a)-(c) is between about 5-10 Torr.

In another aspect of the disclosed embodiments, the method may include (a) introducing a first reactant in vapor phase into the reaction chamber under conditions allowing the first reactant to adsorb onto the substrate surface; (b) introducing a second reactant in vapor phase into the reaction chamber under conditions allowing the second reactant to adsorb onto the substrate surface; and (c) periodically exposing the substrate surface to plasma when the vapor phase flow of the first reactant has ceased in order to drive a surface reaction between the first and second reactants on the substrate surface to form the film, where an RF power used to drive formation of the plasma is greater than about 1.1 Watts per station per square centimeter of substrate area.

In another aspect of the disclosed embodiments, an apparatus for depositing films on a substrate is provided. The apparatus may include a reaction chamber; an inlet port for delivering gas phase reactants to the reaction chamber; and a controller having instructions for (a) introducing a first reactant in vapor phase into the reaction chamber; (b) introducing a second reactant in vapor phase into the reaction chamber; (c) periodically striking a plasma to expose the substrate surface to plasma when the vapor phase flow of the first reactant has ceased in order to drive a surface reaction between the first and second reactants on the substrate surface to form the film; (d) maintaining a pressure in the reaction chamber at greater than 4 Torr; and (e) applying an RF power greater than about 1.1 Watts per station per square centimeter of substrate area to drive formation of the plasma.

In certain embodiments, the controller has instructions for applying RF power greater than about 1.4 Watts per station per square centimeter of substrate area to drive formation of the plasma. For example, the controller may have instructions for applying RF power between about 1.4-4.2 Watts per station per square centimeter of substrate area to drive formation of the plasma. The controller may also have instructions for maintaining a pressure in the reaction chamber at less than about 20 Torr. In some implementations, for example, the controller may have instructions for maintaining the pressure in the reaction chamber between about 5-10 Torr. In certain cases, the controller may have instructions for introducing the first reactant into the reaction chamber during a pulse having a duration less than about 75 ms, or less than about 50 ms. In these or other cases, the controller may have instructions for exposing the substrate surface to plasma during a pulse having a duration less than about 250 ms.

In another aspect of the disclosed embodiments, an apparatus for depositing films on a substrate is provided, having a reaction chamber, an inlet port for delivering gas phase reactants to the reaction chamber; and a controller having instructions for (a) introducing a first reactant in vapor phase into the reaction chamber; (b) introducing a second reactant in vapor phase into the reaction chamber; (c) periodically striking a plasma to expose the substrate surface to plasma when the vapor phase flow of the first reactant has ceased in order to drive a surface reaction between the first and second reactants on the substrate surface to form the film; and (d) maintaining a pressure in the reaction chamber between about 5-10 Torr.

In a further aspect of the disclosed embodiments, an apparatus for depositing films on a substrate is provided, having a reaction chamber, an inlet port for delivering gas phase reactants to the reaction chamber; and a controller having instructions for (a) introducing a first reactant in vapor phase into the reaction chamber; (b) introducing a second reactant in vapor phase into the reaction chamber; (c) periodically striking a plasma to expose the substrate surface to plasma when the vapor phase flow of the first reactant has ceased in order to drive a surface reaction between the first and second reactants on the substrate surface to form the film; and (d) applying an RF power greater than about 1.1 Watts per station per square centimeter of substrate area to drive formation of the plasma.

These and other features will be described in more detail below with reference to the associated drawings.

### BRIEF DESCRIPTION OF THE DRAWINGS

FIG. 1 schematically shows a timing diagram for an example conformal film deposition (CFD) process according to an embodiment of the present disclosure.

FIG. 2 schematically shows a timing diagram for another example CFD process according to an embodiment of the present disclosure.

FIG. 3 schematically shows an example process station according to an embodiment of the present disclosure.

FIG. 4 schematically shows an example process tool including a plurality of process stations and a controller according to an embodiment of the present disclosure.

FIG. 5 schematically shows a timing diagram for another example CFD process including concurrent PECVD and CFD deposition processes and including a sweep phase having a positive time duration between discontinuing a supply of reactant B to the process station and plasma activation according to an embodiment of the present disclosure.

FIG. 6 schematically shows a timing diagram for another example CFD process including concurrent PECVD and CFD deposition processes and excluding a sweep phase between discontinuing a supply of reactant B and plasma activation according to an embodiment of the present disclosure.

FIG. 7 schematically shows a timing diagram for another example CFD process including concurrent PECVD and CFD deposition processes and including an overlap between a supply of reactant B to the process station and plasma activation according to an embodiment of the present disclosure.

FIGS. 8 and 9 provide comparative data showing deposition rate and within-wafer percent non-uniformity for various substrates having silicon dioxide films deposited thereon.

FIG. 10 shows data related to the deposition rate for silicon oxide films deposited at various RF power levels.

FIG. 11 shows data related to the non-uniformity of silicon oxide films deposited over a range of RF power levels.

FIG. 12 shows data related to the deposition rate and non-uniformity of silicon oxide films deposited over a range of power levels.

FIG. 13 shows data related to the deposition rate and non-uniformity of silicon oxide films deposited over a range of RF plasma exposure durations.

FIG. 14 shows data related to deposition rate and non-uniformity of silicon oxide films deposited at different silicon-containing reactant dose durations.

FIG. 15 shows data related to the deposition rate and non-uniformity of silicon oxide films deposited at different RF plasma exposure durations.

### DETAILED DESCRIPTION

Manufacture of semiconductor devices typically involves depositing one or more thin films on a non-planar substrate in an integrated fabrication process. In some aspects of the integrated process it may be useful to deposit thin films that conform to substrate topography. For example, a silicon nitride film may be deposited on top of an elevated gate stack to act as a spacer layer for protecting lightly-doped source and drain regions from subsequent ion implantation processes.

In spacer layer deposition processes, chemical vapor deposition (CVD) processes may be used to form a silicon nitride film on the non-planar substrate, which is then anisotropically etched to form the spacer structure. However, as a distance between gate stacks decreases, mass transport limitations of CVD gas phase reactions may cause “bread-loafing” deposition effects. Such effects typically exhibit thicker deposition at top surfaces of gate stacks and thinner deposition at the bottom corners of gate stacks. Further, because some die may have regions of differing device density, mass transport effects across the wafer surface may result in within-die and within-wafer film thickness variation. These thickness variations may result in over-etching of some regions and under-etching of other regions. This may degrade device performance and/or die yield.

Some approaches to addressing these issues involve atomic layer deposition (ALD). In contrast with a CVD process, where thermally activated gas phase reactions are used to deposit films, ALD processes use surface-mediated deposition reactions to deposit films on a layer-by-layer basis. In one example ALD process, a substrate surface, including a population of surface active sites, is exposed to a gas phase distribution of a first film precursor (P1). Some molecules of P1 may form a condensed phase atop the substrate surface, including chemisorbed species and physisorbed molecules of P1. The reactor is then evacuated to remove gas phase and physisorbed P1 so that only chemisorbed species remain. A second film precursor (P2) is then introduced to the reactor so that some molecules of P2 adsorb to the substrate surface. The reactor may again be evacuated, this time to remove unbound P2. Subsequently, thermal energy provided to the substrate activates surface reactions between adsorbed molecules of P1 and P2, forming a film layer. Finally, the reactor is evacuated to remove reaction by-products and possibly unreacted P1 and P2, ending the ALD cycle. Additional ALD cycles may be included to build film thickness.

Depending on the exposure time of the precursor dosing steps and the sticking coefficients of the precursors, each ALD cycle may deposit a film layer of, in one example, between one-half and three angstroms thick.

Conformal films may also be deposited on planar substrates. For example, antireflective layers for lithographic patterning applications may be formed from planar stacks comprising alternating film types. Such antireflective layers may be approximately 100 to 1000 angstroms thick, making slower ALD processes less attractive than faster CVD processes. However, such anti-reflective layers may also have a lower tolerance for within-wafer thickness variation than many CVD processes may provide. For example, a 600-angstrom thick antireflective layer may tolerate a thickness range of less than 3 angstroms.

Accordingly, various embodiments are provided herein providing processes and equipment for plasma-activated conformal film deposition (CFD) on non-planar and planar substrates. These embodiments incorporate various features employed in some but not all CFD processes, and are typically performed at high pressure and/or high plasma power.

Generally, CFD does not rely on complete purges of one or more reactants prior to reaction to form the film. For example, there may be one or more reactants present in the vapor phase when a plasma (or other activation energy) is struck. Accordingly, one or more of the process steps described in an ALD process may be shortened or eliminated in an example CFD process. Further, in some embodiments, plasma activation of deposition reactions may result in lower deposition temperatures than thermally-activated reactions, potentially reducing the thermal budget of an integrated process.

While embodiments include CFD, the methods described herein are not limited to CFD. Other suitable methods include ALD. For example, embodiments described herein include plasma-activated ALD processes that use high deposition chamber pressure and/or high RF power levels to form highly uniform conformal films at high deposition rates.

Methods for forming films using CFD are described in U.S. patent application Ser. No. 13/084,399, filed on Apr. 11, 2011, and which is incorporated by reference herein for all purposes. For context, a short description of CFD is provided.

The concept of a CFD “cycle” is relevant to the discussion of various embodiments herein. Generally a cycle is the minimum set of operations required to perform a surface deposition reaction one time. The result of one cycle is production of at least a partial film layer on a substrate surface. Typically, a CFD cycle will include only those steps necessary to deliver and adsorb each reactant to the substrate surface, and then react those adsorbed reactants to form the partial layer of film. Of course, the cycle may include certain ancillary steps such as sweeping one or more of the reactants or byproducts and/or treating the partial film as deposited. Generally, a cycle contains only one instance of a unique sequence of operations. As an example, a cycle may include the following operations: (i) delivery/adsorption of reactant A, (ii) delivery/adsorption of reactant B, (iii) sweep B out of the reaction chamber, and (iv) apply plasma to drive a surface reaction of A and B to form the partial film layer on the surface.

### High Radio Frequency Power Conformal Film Deposition Processes

One aspect of the embodiments herein is a high power radio frequency (RF) CFD process. Without being bound by a particular mechanism, it is believed that high-frequency (HF) high power RF power results in improved conversion of precursor materials on the surface of the substrate. This improved conversion may also result in better etch rates and higher stress films.

The RF power used to drive plasma generation and film formation may be described in various ways. In some cases, a multi-station reaction chamber is used, in which case there may be multiple RF generators acting on multiple substrates. The RF power levels recited herein reflect the power delivered in a single station, whether it be a single station reactor or a single station in a multi-station tool. Further, the absolute level of RF power delivered, when recited in terms of Watts, relates to the power delivered when processing a 300 mm wafer. The techniques herein may be used to process substrates of any size, and the power levels scale with the area of the substrate. As such, the RF power levels may also be recited in terms of a power density (e.g., power delivered divided by the area of the substrate). The substrate area is calculated as the surface area of the plating face of the substrate, without taking into account any non-planar features. In other words, a 300 mm diameter substrate is considered to have a substrate area of about 707 cm², regardless of whether there are features present on the surface that would technically increase the surface area above this baseline amount. It should be noted that while low-frequency (LF) RF power may be employed in some embodiments in addition to HF RF power, the power levels described herein refer to high-frequency (HF) RF power. Where LF RF power is used, it may be in the range of about 750 W/station or less.

Conventional CFD processes typically utilize RF power levels below about 625 Watts per station (less than about 0.9 W/cm² per station). In contrast, in various disclosed embodiments, the power is greater than about 800 Watts per station (greater than about 1.1 W/cm² per station). For example, the power may be greater than about 1000 Watts per station (greater than about 1.4 W/cm² per station). In some cases, the RF power is between about 1000-3000 Watts per station (between about 1.4-4.3 W/cm² per station), for example between about 1000-2500 Watts per station (between about 1.4-3.5 W/cm² per station). In some cases where high RF power is not utilized, however, the RF power may be as low as about 12 Watts/station.

Among other benefits, these high RF power levels allow the plasma exposure time to be minimized, thereby reducing processing time and increasing throughput. High RF power may also contribute to improved film uniformity.

### High Pressure CFD Processes

Another aspect disclosed herein involves high pressure CFD processes. High pressure processes yield significant improvement in particle performance and may result in lower dose times for introducing certain reactants, thereby reducing processing time and increasing throughput. In conventional CFD processes, the pressure is typically maintained at or below 3.5 Torr, for example 3 Torr. According to various embodiments, pressure in the reaction chamber during at least plasma activation is greater than 4 Torr, and may be between about 5 and 100 Torr. In some embodiments, it may between about 5 and 20 Torr, for example between about 5 and 10 Torr. In a particular example, the pressure is about 6 Torr. This pressure may also be used during the remainder of the cycle.

In some cases, an optional pump down to less than about 1 Torr (e.g., using a setpoint of 0) may be employed after the plasma is extinguished, either before, during or after a post-plasma purge if performed. It has been found that for some embodiments, a pump down results in a higher quality film.

Performing the CFD depositions in the pressure regime described (e.g., at or greater than 5 Torr) reduces defects due to particle contamination. Without being bound by a particular theory, it is believed that this improvement is due to better plasma confinement between the showerhead and the pedestal at high pressures, and reduction of parasitic plasma in remote regions of the chamber. This reduces the likelihood of particles flaking in the remote chamber areas.

Another advantage arising from better plasma confinement is improved film uniformity. Under certain low pressure reaction conditions, there is a substantial differential in film thickness between the center of a substrate and the edges of a substrate. One reason for this difference is that under a low pressure regime (e.g., under about 4 Torr), the plasma tends to spread more throughout the reactor, and the distribution/density of species within the plasma becomes non-uniform over different regions of the substrate. In effect, the less uniform plasma results in a less uniform film. By instead using a high pressure regime, the plasma is better confined and more uniform, resulting in a more uniform film.

Further, higher pressures result in more efficient delivery of reactant to the substrate, as the reactants are less likely to spread into the remote areas of the chamber. As such, the dosing time required to adequately saturate the substrate surface for reaction is minimized, and throughput is increased.

### High RF Power, High Pressure CFD Processes

Various disclosed embodiments utilize both high pressure and high RF power to deposit material on a substrate. The pressures and power levels related above may be used in conjunction with one another to achieve such processes. High pressure, high RF power processes have been shown to result in very uniform films (e.g., within wafer non-uniformity of about 0.3%). These results are discussed in the Experimental section below.

### Reactants

The description herein uses the terms “principal” and “auxiliary” reactants. As used herein, a principal reactant contains an element that is solid at room temperature, which element is contributed to the film formed by CFD. Examples of such elements are metals (e.g., aluminum, titanium, etc.), semiconductors (e.g., silicon and germanium), and non-metals or metalloids (e.g., boron). As used herein, an auxiliary reactant is any reactant that is not a principal reactant. The term co-reactant is sometimes used to refer to auxiliary reactants. Examples of auxiliary reactants include oxygen, ozone, hydrogen, carbon monoxide, nitrous oxide, ammonia, alkyl amines, and the like.

The CFD process may be employed to deposit any of a number of different types of film. Nitrides and oxides are featured dielectric materials, but carbides, oxynitrides, carbon-doped oxides, borides, etc. may also be formed. Oxides include a wide range of materials including undoped silicate glass (USG), doped silicate glass. Examples of doped glasses included boron doped silicate glass (BSG), phosphorus doped silicate glass (PSG), and boron phosphorus doped silicate glass (BPSG).

The embodiments herein are not limited to particular reactants or film types. However, an exemplary list of reactants is provided below.

In certain embodiments, the deposited film is a silicon-containing film. In these cases, the silicon-containing reactant may be for example, a silane, a halosilane or an aminosilane. A silane contains hydrogen and/or carbon groups, but does not contain a halogen. Examples of silanes are silane (SiH₄), disilane (Si₂H₆), and organo silanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, and the like. A halosilane contains at least one halogen group and may or may not contain hydrogens and/or carbon groups. Examples of halosilanes are iodosilanes, bromosilanes, chlorosilanes and fluorosilanes. Although halosilanes, particularly fluorosilanes, may form reactive halide species that can etch silicon materials, in certain embodiments described herein, the silicon-containing reactant is not present when a plasma is struck. Specific chlorosilanes are tetrachlorosilane (SiCl₄), trichlorosilane (HSiCl₃), dichlorosilane (H₂SiCl₂), monochlorosilane (ClSiH₃), chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like. An aminosilane includes at least one nitrogen atom bonded to a silicon atom, but may also contain hydrogens, oxygens, halogens and carbons. Examples of aminosilanes are mono-, di-, tri- and tetra-aminosilane (H₃Si(NH₂)₄, H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tertiarybutylamino)silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃ and the like. A further example of an aminosilane is trisilylamine (N(SiH₃)).

In other cases, the deposited film contains metal. Examples of metal-containing films that may be formed include oxides and nitrides of aluminum, titanium, hafnium, tantalum, tungsten, manganese, magnesium, strontium, etc., as well as elemental metal films. Example precursors may include metal alkylamines, metal alkoxides, metal alkylamides, metal halides, metal β-diketonates, metal carbonyls, organometallics, etc. Appropriate metal-containing precursors will include the metal that is desired to be incorporated into the film. For example, a tantalum-containing layer may be deposited by reacting pentakis(dimethylamido)tantalum with ammonia or another reducing agent. Further examples of metal-containing precursors that may be employed include trimethylaluminum, tetraethoxytitanium, tetrakis-dimethyl-amido titanium, hafnium tetrakis(ethylmethylamide), bis(cyclopentadienyl)manganese, bis(n-propylcyclopentadienyl)magnesium, etc.

In some embodiments, the deposited film contains nitrogen, and a nitrogen-containing reactant must be used. A nitrogen-containing reactant contains at least one nitrogen, for example, ammonia, hydrazine, amines (e.g., amines bearing carbon) such as methylamine, dimethylamine, ethylamine, isopropylamine, t-butylamine, di-t-butylamine, cyclopropylamine, sec-butylamine, cyclobutylamine, isoamylamine, 2-methylbutan-2-amine, trimethylamine, diisopropylamine, diethylisopropylamine, di-t-butylhydrazine, as well as aromatic containing amines such as anilines, pyridines, and benzylamines. Amines may be primary, secondary, tertiary or quaternary (for example, tetraalkylammonium compounds). A nitrogen-containing reactant can contain heteroatoms other than nitrogen, for example, hydroxylamine, t-butyloxycarbonyl amine and N-t-butyl hydroxylamine are nitrogen-containing reactants.

In certain implementations, an oxygen-containing oxidizing reactant is used. Examples of oxygen-containing oxidizing reactants include oxygen, ozone, nitrous oxide, carbon monoxide, etc.

While many examples discussed herein include two reactants (e.g., A and B, or a principal reactant and an auxiliary reactant), it will be appreciated that any suitable number of reactants may be employed within the scope of the present disclosure. In some embodiments, a single reactant and an inert gas used to supply plasma energy for a surface decomposition reaction of the reactant may be used. Alternatively, some embodiments may use three or more reactants to deposit a film.

### Timing and Other Process Considerations

The embodiments herein may use various different process sequences. One possible process includes the following sequence of operations: (1) flow auxiliary reactant continuously, (2) provide dose of silicon-containing or other principle reactant, (3) purge 1, (4) expose substrate to RF plasma, (5) purge 2. Table 1 below recites non-limiting examples of process parameters that may be used to implement this technique to deposit a silicon oxide film.

TABLE 1

| | Oxidant | Si dose | Purge 1 | RF plasma | Purge 2 |
|---|---|---|---|---|---|
| Compound(s) | O₂, N₂O, CO₂, | Silanes, | Inert gas, | NA | Inert gas, |
| | mixtures, | e.g., BTBAS | e.g., Ar/N₂ | | e.g., Ar/N₂ |
| | e.g., mixture | | | | |
| | of N₂O and O₂ | | | | |
| Flow Rate | 3-10 slm, | 0.5-5 ml/min, | 10-90 slm, | NA | 10-90 slm, |
| | e.g. 4.5 slm | e.g., 2 ml/min | e.g., 45 slm | | e.g., 45 slm |
| | O₂ + 5 slm | | | | |
| | N₂O premixed | | | | |
| Time | Continuous | 0.1-2 s, | 0.1-5 s, | 0.1-5 s, | Optional, if |
| | | e.g., 0.8 s | e.g., 0.5 s | e.g. 1 s | performed |
| | | | | | 0.01-5 s, |
| | | | | | e.g., 0.09 s |

Another alternative process includes the following sequence of operations: (1) flow inert gas continuously, (2) provide dose of silicon-containing or other principle reactant, (3) purge 1, (4) expose substrate to RF plasma while providing dose of oxidant or other auxiliary reactant, (5) purge 2. Table 2 below recites various non-limiting examples of process parameters that may be used to implement this process flow to deposit a silicon oxide film.

TABLE 2

| | Oxidant | Si dose | Purge 1 | RF plasma | Purge 2 |
|---|---|---|---|---|---|
| Compound(s) | O₂, N₂O, CO₂, | Silanes, | Inert gas, | NA | Inert gas, |
| | mixtures, | e.g. BTBAS | e.g., Ar/N₂ | | e.g., Ar/N₂ |
| | e.g., mixture | | | | |
| | of N₂O and O₂ | | | | |
| Flow Rate | 3-10 slm, | 0.5-5 ml/min, | 10-90 slm, | NA | 10-90 slm, |
| | e.g. 4.5 slm | e.g., 2 ml/min | e.g., 45 slm | | e.g., 45 slm |
| | O₂ + 5 slm | | | | |
| | N₂O premixed | | | | |
| Time | 50 ms-5 s, | 50 ms-1 s. | Continuous, | 50 ms-5 s, | Continuous, |
| | e.g., 0.15 s | e.g., 0.2 s | inert gas only: | e.g., 0.15 s | inert gas only: |
| | Concurrent with | | 0.1-5 s, | | Optional, if |
| | RF or may flow | | e.g., 0.4 s | | performed |
| | oxidant 0.001-1 s | | | | 0.01-5 s, |
| | prior to RF to | | | | e.g., 0.09 s |
| | stabilize flow | | | | |

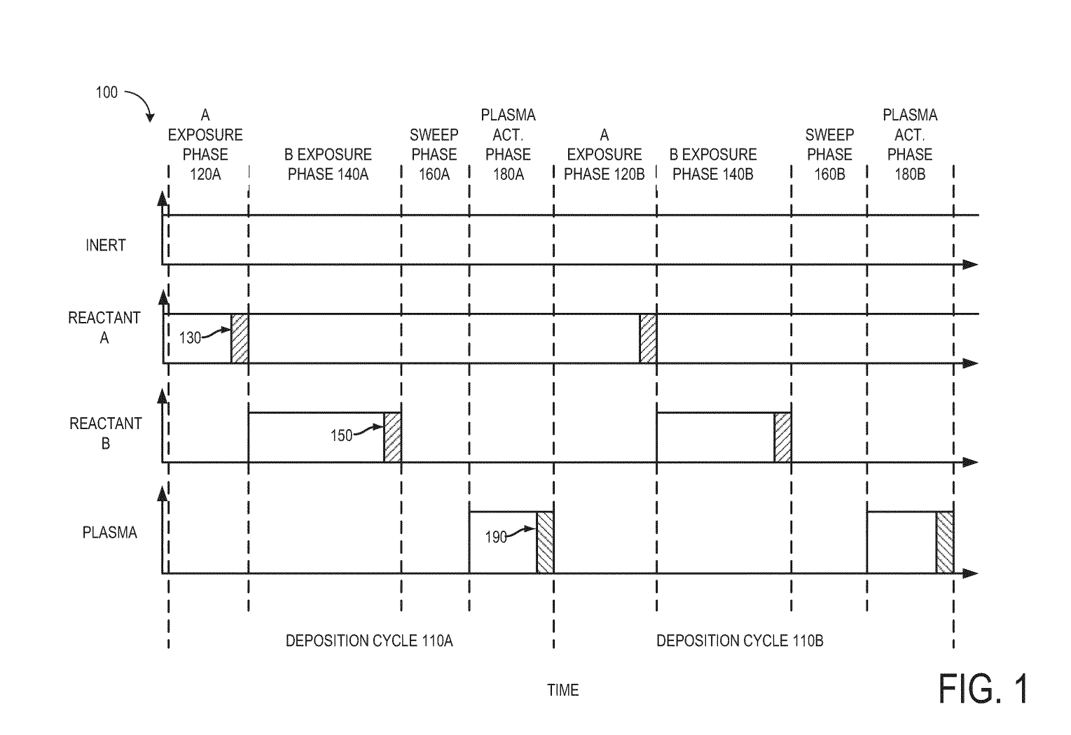

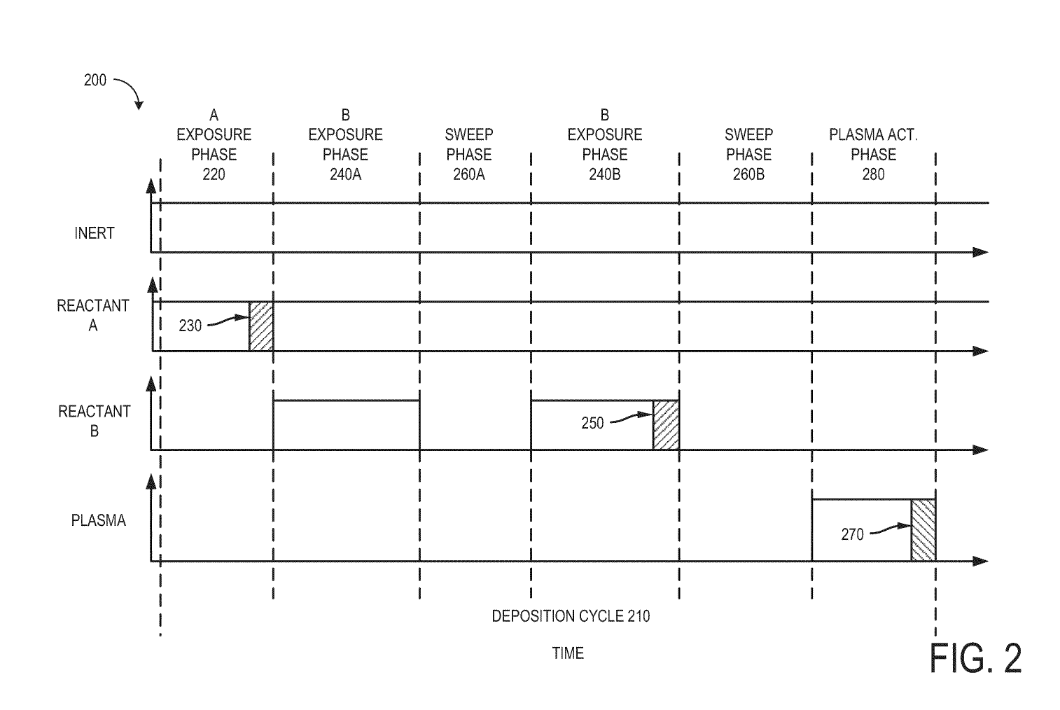

The compounds, flow rates, and dosage times in the above tables are examples. Any appropriate silicon-containing reactant and oxidant may be used for the deposition of silicon oxides. Similarly, for the deposition of silicon nitrides, any appropriate silicon-containing reactant and nitrogen-containing reactant may be used. Further, for the deposition of metal oxides or metal nitrides, any appropriate metal-containing reactants and co-reactants may be used. The techniques herein are beneficial in implementing a wide variety of film chemistries. Flow rates and times outside the ranges provided may be appropriate in certain embodiments. Example flow rates are given for 300 mm wafers and may be scaled appropriately for wafers of other sizes. Other process flows may also be used, some of which are described with reference to the timing diagrams shown in FIGS. 1 and 2, below.

In some cases, one of the reactants may be delivered continuously (e.g., even during delivery of other reactants and/or during plasma exposure). The continuously flowing reactant may be delivered to the reaction chamber in conjunction with a carrier gas—e.g., argon.

One advantage of the continuous flow embodiment is that the established flow avoids the delays and flow variations caused by transient initialization and stabilization of flow associated with turning the flow on and off.

As a specific example, an oxide film may be deposited by a conformal film deposition process using a principal reactant (sometimes referred to as a “solid component” precursor or, in this example, simply “reactant B”). Bis(tert-butylamino)silane (BTBAS) is one such principal reactant. In this example, the oxide deposition process involves delivery of an oxidant such as oxygen or nitrous oxide, which flows initially and continuously during delivery of the principal reactant in distinct exposure phases. The oxidant also continues to flow during distinct plasma exposure phases. See for example the sequence depicted in FIG. 1.

In some specific examples, the reactant that flows continuously is an auxiliary reactant. The continuously flowing reactant may be provided at a constant flow rate or at varied but controlled flow rate. In the latter case, as an example, the flow rate of an auxiliary reactant may drop during an exposure phase when the primary reactant is delivered. For example, in oxide deposition, the oxidant (e.g., oxygen or nitrous oxide) may flow continuously during the entire deposition sequence, but its flow rate may drop when the primary reactant (e.g., BTBAS) is delivered. This increases the partial pressure of BTBAS during its dosing, thereby reducing the exposure time needed to saturate the substrate surface. Shortly before igniting the plasma, the flow of oxidant may be increased to reduce the likelihood that BTBAS is present during the plasma exposure phase. In some embodiments, the continuously flowing reactant flows at a varied flow rate over the course of two or more deposition cycles. For example, the reactant may flow at a first flow rate during a first CFD cycle and at a second flow rate during a second CFD cycle.

Where multiple auxiliary reactants are used, they can be mixed prior to delivery to the reaction chamber, or delivered as separate streams. In some embodiments, the auxiliary reactant is delivered continuously with an inert gas flow delivered in a burst for purge operations. In some embodiments, an inert gas flow may be continuous, with or without the inert gas flow rate increased for the purge operation. An optional purge can occur after the plasma is extinguished.

The concept of a CFD “sweep” or “purge” step or phase appears in the discussion various embodiments herein. Generally, a sweep phase removes or purges one of the vapor phase reactant from a reaction chamber and typically occurs only after delivery of such reactant is completed. In other words, that reactant is no longer delivered to the reaction chamber during the sweep phase. However, the reactant remains adsorbed on the substrate surface during the sweep phase. Typically, the sweep serves to remove any residual vapor phase reactant in the chamber after the reactant is adsorbed on the substrate surface to the desired level. A sweep phase may also remove weakly adsorbed species (e.g., certain precursor ligands or reaction by-products) from the substrate surface. In ALD, the sweep phase has been viewed as necessary to prevent gas phase interaction of two reactants or interaction of one reactant with a thermal, plasma or other driving force for the surface reaction. In general, and unless otherwise specified herein, a sweep/purge phase may be accomplished by (i) evacuating a reaction chamber, and/or (ii) flowing gas not containing the species to be swept out through the reaction chamber. In the case of (ii), such gas may be, for example, an inert gas or an auxiliary reactant such as a continuously flowing auxiliary reactant.

Different embodiments may implement sweep phases at different times. For example, in certain cases a sweep step may occur at any of the following times: (1) after delivery of a principal reactant, (2) between pulses of delivering a principal reactant, (3) after delivery of an auxiliary reactant, (4) before plasma exposure, (5) after plasma exposure, and (6) any combination of (1)-(5). Some of these timeframes may overlap. It has been shown that a first sweep performed after delivery of the principal reactant, and a second sweep performed after plasma excitation, are particularly useful in depositing uniform films.

Unlike many other deposition processes, particularly those requiring thermal activation, the CFD process may be conducted at a relatively low temperature. Generally, the CFD temperature will be between about 20 and 400 C. Such temperature may be chosen to permit deposition in the context of a temperature sensitive process such as deposition on a photoresist core. In a specific embodiment, a temperature of between about 20 and 100 C is used for double patterning applications (using, e.g., photoresist cores). In another embodiment, a temperature of between about 200 and 350 C is employed for memory fabrication processing.

As suggested above, CFD is well suited for depositing films in advanced technology nodes. Thus, for example, CFD processing may be integrated in processes at the 32 nm node, the 22 nm node, the 16 nm node, the 11 nm node, and beyond any of these. These nodes are described in the International Technology Roadmap for Semiconductors (ITRS), the industry consensus on microelectronic technology requirements for many years. Generally they reference one-half pitch of a memory cell. In a specific example, the CFD processing is applied to “2X” devices (having device features in the realm of 20-29 nm) and beyond.

While most examples of CFD films presented herein concern silicon based microelectronic devices, the films may also find application in other areas. Microelectronics or optoelectronics using non-silicon semiconductors such as GaAs and other III-V semiconductors, as well as II-VI materials such as HgCdTe may profit from using the CFD processes disclosed herein. Applications for conformal dielectric films in the solar energy field, such as photovoltaic devices, in the electrochromics field, and other fields are possible.

Other example applications for CFD films include, but are not limited to conformal low-k films (e.g., k approximately 3.0 or lower in some non-limiting examples) for back-end-of-line interconnect isolation applications, conformal silicon nitride films for etch stop and spacer layer applications, conformal antireflective layers, and copper adhesion and barrier layers. Many different compositions of low-k dielectrics for BEOL processing can be fabricated using CFD. Examples include silicon oxides, oxygen doped carbides, carbon doped oxides, oxynitrides, and the like.

FIG. 1 schematically shows a timing diagram 100 for an example embodiment of a plasma-activated CFD process. Two full CFD cycles are depicted. As shown, each includes an exposure to reactant A phase 120, directly followed by an exposure to reactant B phase 140, a sweep of reactant B phase 160, and finally a plasma activation phase 180. Plasma energy provided during plasma activation phases 180A and 180B activates a reaction between surface adsorbed reactant species A and B. In the depicted embodiments, no sweep phase is performed after one reactant (reactant A) is delivered. In fact, this reactant flows continuously during the film deposition process. Thus, plasma is ignited while reactant A is in the gas phase. In the depicted embodiment, reactant gases A and B may co-exist in the gas phase without reacting. Accordingly, one or more of the process steps described in the ALD process may be shortened or eliminated in this example CFD process. For example, sweep steps after A Exposure Phases 120A and 120B may be eliminated.

FIG. 1 also shows an embodiment of a temporal progression of an example CFD process phases for various CFD process parameters. FIG. 1 depicts two example deposition cycles 110A and 110B, though it will be appreciated that any suitable number of deposition cycles may be included in a CFD process to deposit a desired film thickness. Example CFD process parameters include, but are not limited to, flow rates for inert and reactant species, plasma power and frequency, substrate temperature, and process station pressure.

A CFD cycle typically contains an exposure phase for each reactant. During this “exposure phase,” a reactant is delivered to a process chamber to cause adsorption of the reactant on the substrate surface. Typically, at the beginning of an exposure phase, the substrate surface does not have any appreciable amount of the reactant adsorbed. In FIG. 1, at reactant A exposure phases 120A and B, reactant A is supplied at a controlled flow rate to a process station to saturate exposed surfaces of a substrate. Reactant A may be any suitable deposition reactant; e.g., a principal reactant or an auxiliary reactant. In one example where CFD produces a silicon dioxide film, reactant A may be oxygen.

In the embodiment shown in FIG. 1, reactant A flows continuously throughout deposition cycles 110A and 110B. Unlike a typical ALD process, where film precursor exposures are separated to prevent gas phase reaction, reactants A and B are allowed to mingle in the gas phase of some embodiments of a CFD process. As indicated above, in some embodiments reactants A and B are chosen so that they can co-existence in the gas phase without appreciably reacting with one another under conditions encountered in the reactor prior to application of plasma energy or the activation of the surface reaction. In some cases, the reactants are chosen such that (1) a reaction between them is thermodynamically favorable (i.e., Gibb's free energy <0) and (2) the reaction has a sufficiently high activation energy that there is negligible reaction at the desired deposition temperature absent plasma excitation.

Continuously supplying reactant A to the process station may reduce or eliminate a reactant A flow rate turn-on and stabilization time compared to an ALD process where reactant A is first turned on, then stabilized and exposed to the substrate, then turned off, and finally removed from a reactor. While the embodiment shown in FIG. 1 depicts reactant A exposure phases 120A and B as having a constant flow rate, it will be appreciated that any suitable flow of reactant A, including a variable flow, may be employed within the scope of the present disclosure. Further, while FIG. 1 shows reactant A having a constant flow rate during the entire CFD cycle (deposition cycle 110A), this need not be the case. For example, the flow rate of reactant A may decrease during B exposure phases 140A and 140B. This may increase the partial pressure of B and thereby increase the driving force of reactant B adsorbing on the substrate surface.

In some embodiments, reactant A exposure phase 120A may have a duration that exceeds a substrate surface saturation time for reactant A. For example, the embodiment of FIG. 1 includes a reactant A post-saturation exposure time 130 in reactant A exposure phase 120A. Optionally, reactant A exposure phase 120A includes a controlled flow rate of an inert gas. Example inert gases include, but are not limited to, nitrogen, argon, and helium. The inert gas may be provided to assist with pressure and/or temperature control of the process station, evaporation of a liquid precursor, more rapid delivery of the precursor and/or as a sweep gas for removing process gases from the process station and/or process station plumbing.

At Reactant B exposure phase 140A of the embodiment shown in FIG. 1, reactant B is supplied at a controlled flow rate to the process station to saturate the exposed substrate surface. In one example silicon dioxide film, reactant B may be BTBAS. While the embodiment of FIG. 1 depicts reactant B exposure phase 140A as having a constant flow rate, it will be appreciated that any suitable flow of reactant B, including a variable flow, may be employed within the scope of the present disclosure. Further, it will be appreciated that reactant B exposure phase 140A may have any suitable duration. In some embodiments, reactant B exposure phase 140A may have a duration exceeding a substrate surface saturation time for reactant B. For example, the embodiment shown in FIG. 1 depicts a reactant B post-saturation exposure time 150 included in reactant B exposure phase 140A. Optionally, reactant B exposure phase 140A may include a controlled flow of a suitable inert gas, which, as described above, may assist with pressure and/or temperature control of the process station, evaporation of a liquid precursor, more rapid delivery of the precursor and may prevent back-diffusion of process station gases.

While the CFD process embodiment depicted in FIG. 1 is plasma activated, it will be appreciated that other non-thermal energy sources may be used within the scope of the present disclosure. Non-limiting examples of non-thermal energy sources include, but are not limited to, ultraviolet lamps, downstream or remote plasma sources, inductively-coupled plasmas, and microwave surface wave plasmas.

In some scenarios, surface adsorbed B species may exist as discontinuous islands on the substrate surface, making it difficult to achieve surface saturation of reactant B. Various surface conditions may delay nucleation and saturation of reactant B on the substrate surface. For example, ligands released on adsorption of reactants A and/or B may block some surface active sites, preventing further adsorption of reactant B. Accordingly, in some embodiments, continuous adlayers of reactant B may be provided by modulating a flow of and/or discretely pulsing reactant B into the process station during reactant B exposure phase 140A. This may provide extra time for surface adsorption and desorption processes while conserving reactant B compared to a constant flow scenario.

Additionally or alternatively, in some embodiments, one or more sweep phases may be included between consecutive exposures of reactant B. For example, the embodiment of FIG. 2 schematically shows an example CFD process timing diagram 200 for a deposition cycle 210. At reactant B exposure phase 240A, reactant B is exposed to the substrate surface. Subsequently, at sweep phase 260A, reactant B is turned off, and gas phase species of reactant B are removed from the process station. In one scenario, gas phase reactant B may be displaced by a continuous flow of reactant A and/or the inert gas. In another scenario, gas phase reactant B may be removed by evacuating the process station. Removal of gas phase reactant B may shift an adsorption/desorption process equilibrium, desorbing ligands, promoting surface rearrangement of adsorbed B to merge discontinuous islands of adsorbed B. At reactant B exposure phase 240B, reactant B is again exposed to the substrate surface. While the embodiment shown in FIG. 2 include one instance of a reactant B sweep and exposure cycle, it will be appreciated that any suitable number of iterations of alternating sweep and exposure cycles may be employed within the scope of the present disclosure.

Returning to the embodiment of FIG. 1, prior to activation by the plasma at 180A, gas phase reactant B may be removed from the process station in sweep phase 160A in some embodiments. A CFD cycle may include one or more sweep phases in addition to the above-described exposure phases. Sweeping the process station may avoid gas phase reactions where reactant B is susceptible to plasma activation. Further, sweeping the process station may remove surface adsorbed ligands that may otherwise remain and contaminate the film. Examples sweep gases include, but are not limited to, argon, helium, and nitrogen. In the embodiment shown in FIG. 1, sweep gas for sweep phase 160A is supplied by the inert gas stream. In some embodiments, sweep phase 160A may include one or more evacuation subphases for evacuating the process station. Alternatively, it will be appreciated that sweep phase 160A may be omitted in some embodiments.

Sweep phase 160A may have any suitable duration. In some embodiments, increasing a flow rate of a one or more sweep gases may decrease the duration of sweep phase 160A. For example, a sweep gas flow rate may be adjusted according to various reactant thermodynamic characteristics and/or geometric characteristics of the process station and/or process station plumbing for modifying the duration of sweep phase 160A. In one non-limiting example, the duration of a sweep phase may be optimized by adjustment of the sweep gas flow rate. This may reduce deposition cycle time, which may improve substrate throughput.

A CFD cycle typically includes an “activation phase” in addition to the exposure and optional sweep phases described above. The activation phase serves to drive the reaction of the one or more reactants adsorbed on the substrate surface. At plasma activation phase 180A of the embodiment shown in FIG. 1, plasma energy is provided to activate surface reactions between surface adsorbed reactants A and B. For example, the plasma may directly or indirectly activate gas phase molecules of reactant A to form reactant A radicals. These radicals may then interact with surface adsorbed reactant B, resulting in film-forming surface reactions. Plasma activation phase 180A concludes deposition cycle 110A, which in the embodiment of FIG. 1 is followed by deposition cycle 110B, commencing with reactant A exposure phase 120B.

In some embodiments, the plasma ignited in plasma activation phase 180A may be formed directly above the substrate surface. This may provide a greater plasma density and enhanced surface reaction rate between reactants A and B. For example, plasmas for CFD processes may be generated by applying a radio frequency (RF) field to a low-pressure gas using two capacitively coupled plates. In alternative embodiments, a remotely generated plasma may be generated outside of the main reaction chamber.

Any suitable gas may be used to form the plasma. In a first example, and inert gas such as argon or helium may be used to form the plasma. In a second example, a reactant gas such as oxygen or ammonia may be used to form the plasma. In a third example, a sweep gas such as nitrogen may be used to form the plasma. Of course, combinations of these categories of gases may be employed. Ionization of the gas between the plates by the RF field ignites the plasma, creating free electrons in the plasma discharge region. These electrons are accelerated by the RF field and may collide with gas phase reactant molecules. Collision of these electrons with reactant molecules may form radical species that participate in the deposition process. It will be appreciated that the RF field may be coupled via any suitable electrodes. Non-limiting examples of electrodes include process gas distribution showerheads and substrate support pedestals. It will be appreciated that plasmas for CFD processes may be formed by one or more suitable methods other than capacitive coupling of an RF field to a gas.

Plasma activation phase 180A may have any suitable duration. In some embodiments, plasma activation phase 180A may have a duration that exceeds a time for plasma-activated radicals to interact with all exposed substrate surfaces and adsorbates, forming a continuous film atop the substrate surface. For example, the embodiment shown in FIG. 1 includes a plasma post-saturation exposure time 190 in plasma activation phase 180A.

In one scenario, a CFD process may deposit a conformal silicon dioxide film on a non-planar substrate. For example, a CFD silicon dioxide film may be used for gap fill of structures, such as a trench fill of shallow trench isolation (STI) structures. While the various embodiments described below relate to a gap fill application, it will be appreciated that this is merely a non-limiting, illustrative application, and that other suitable applications, utilizing other suitable film materials, may be within the scope of the present disclosure. Other applications for CFD silicon dioxide films include, but are not limited to, interlayer dielectric (ILD) applications, intermetal dielectric (IMD) applications, pre-metal dielectric (PMD) applications, dielectric liners for through-silicon via (TSV) applications, resistive RAM (ReRAM) applications, and/or stacked capacitor fabrication in DRAM applications.

Doped silicon oxide may be used as a diffusion source for boron, phosphorus, or even arsenic dopants. For example, a boron doped silicate glass (BSG), a phosphorus doped silicate glass (PSG), or even a boron phosphorus doped silicate glass (BPSG) could be used. Doped CFD layers can be employed to provide conformal doping in, for example, three-dimensional transistor structures such as multi-gate FinFET's and three-dimensional memory devices. Conventional ion implanters cannot easily dope sidewalls, especially in high aspect ratio structures.

CFD doped oxides as diffusion sources have various advantages. First, they provide high conformality at low temperature. In comparison, low-pressure CVD produced doped TEOS (tetraethylorthosilicate) is known but requires deposition at high temperature, and sub-atmospheric CVD and PECVD doped oxide films are possible at lower temperature but have inadequate conformality. Conformality of doping is important, but so is conformality of the film itself, since the film typically is a sacrificial application and will then need to be removed. A non-conformal film typically faces more challenges in removal, i.e. some areas can be overetched.

Additionally, CFD provides extremely well controlled doping concentration. As mentioned, a CFD process can provide from a few layers of undoped oxide followed by a single layer of doping. The level of doping can be tightly controlled by the frequency with which the doped layer is deposited and the conditions of the doping cycle. In certain embodiments, the doping cycle is controlled by for instance using a dopant source with significant steric hindrance. In addition to conventional silicon-based microelectronics, other applications of CFD doping include microelectronics and optoelectronics based on III-V semiconductors such as GaAs and II-VI semiconductors such as HgCdTe, photovoltaics, flat panel displays, and electrochromic technology.

In some embodiments, a plasma generator may be controlled to provide intermittent pulses of plasma energy during a plasma activation phase. For example, the plasma may be pulsed at one or more frequencies including, but not limited to, frequencies between of 10 Hz and 500 Hz. This may enhance step coverage by reducing a directionality of ion bombardment in comparison to a continuous plasma. Further, this may reduce ion bombardment damage to the substrate. For example, photoresist substrates may be eroded by ion bombardment during a continuous plasma. Pulsing the plasma energy may reduce photoresist erosion.

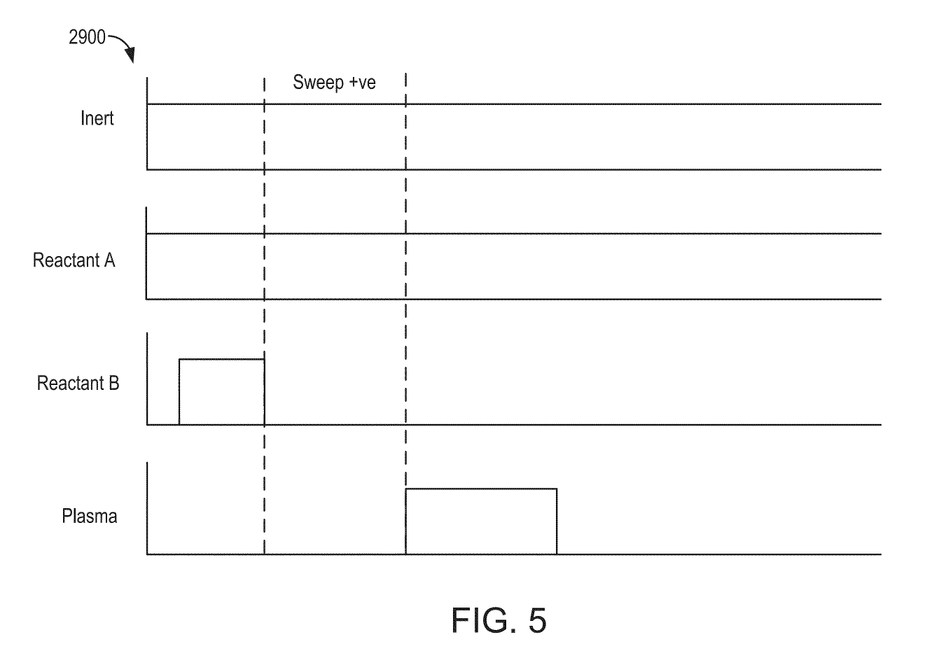

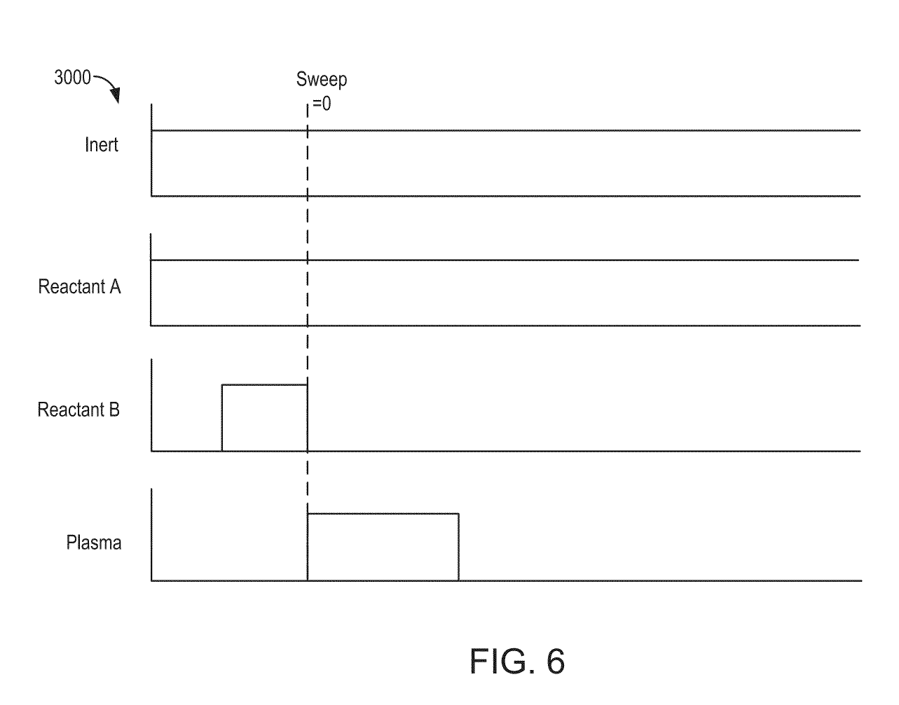

Concurrent PECVD-type and CFD-type reactions may occur where reactant B co-exists with reactant A in a plasma environment. In some embodiments, co-existence of reactants in a plasma environment may result from a persistence of reactant B in a process station after a supply of reactant B has been discontinued, continuing an exposure of reactant B to the substrate. For example, FIG. 5 shows a timing diagram 2900 for an embodiment of a CFD process including a sweep phase having a positive time duration between discontinuing a supply of reactant B to the process station and plasma activation. As another example, FIG. 6 shows another timing diagram 3000 for an embodiment of a CFD process excluding a sweep phase (e.g., having a sweep time=0) between discontinuing a supply of reactant B and plasma activation.

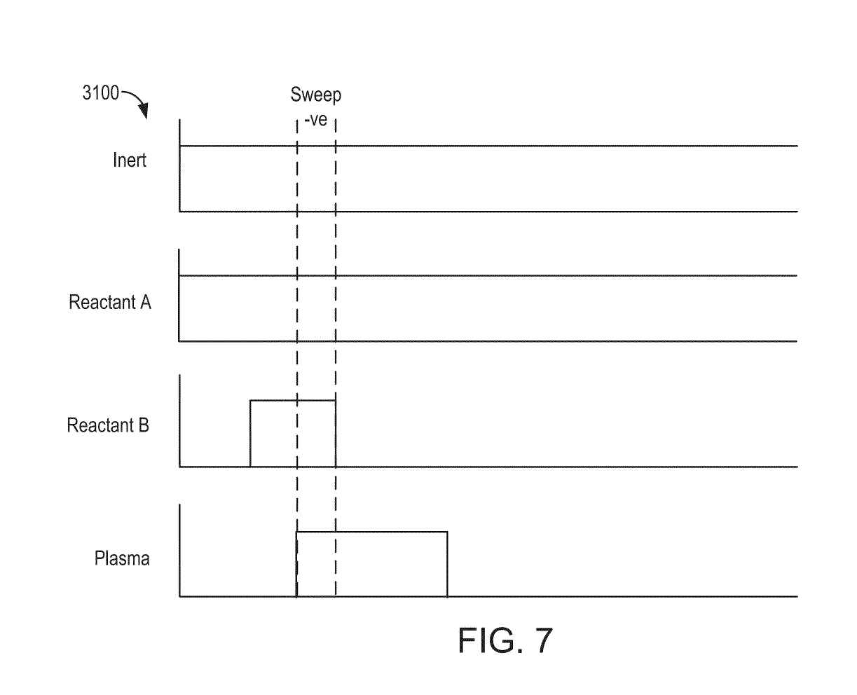

In some embodiments, co-existence of reactants in a plasma environment may result from concurrent supply of reactant B to the process station and plasma activation. For example, FIG. 7 shows a timing diagram 3100 for an embodiment of a CFD process having an overlap (indicated by a “negative” sweep time) between a supply of reactant B to the process station and plasma activation.

While the various CFD deposition processes described above have been directed at depositing, treating, and/or etching single film types, it will be appreciated that some CFD processes within the scope of the present disclosure may include in-situ deposition of a plurality of film types. For example, alternating layers of film types may be deposited in-situ. In a first scenario, a double spacer for a gate device may be fabricated by in-situ deposition of a silicon nitride/silicon oxide spacer stack. This may reduce cycle time and increase process station throughput, and may avoid interlayer defects formed by potential film layer incompatibility. In a second scenario, an antireflective layer for lithographic patterning applications may be deposited as a stack of SiON or amorphous silicon and SiOC with tunable optical properties.

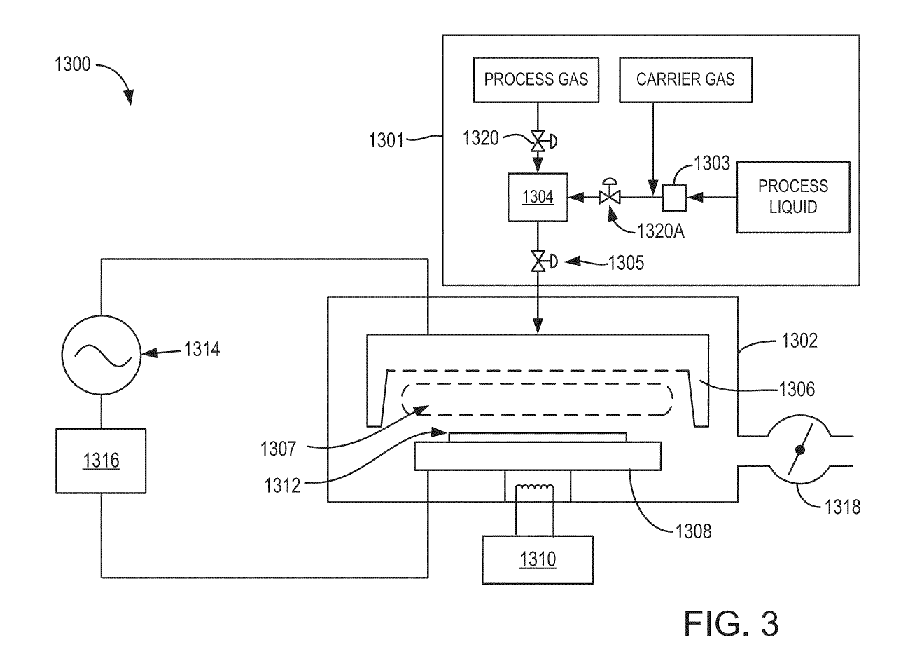

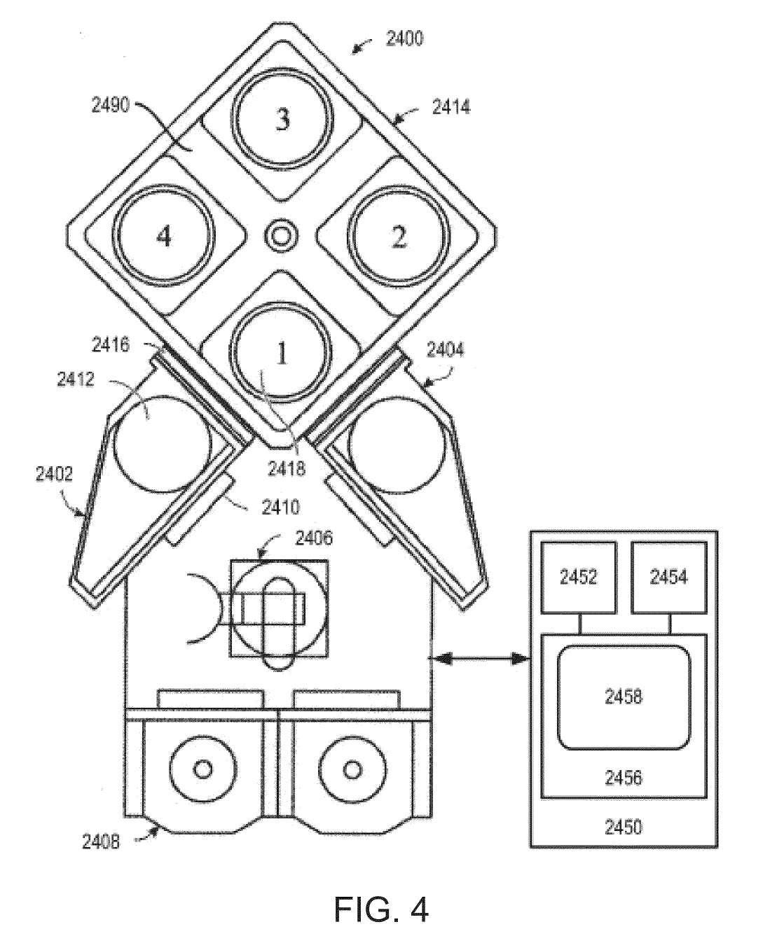

It will be appreciated that any suitable process station may be employed with one or more of the embodiments described above. For example, FIG. 3 schematically shows an embodiment of a CFD process station 1300. For simplicity, CFD process station 1300 is depicted as a standalone process station having a process chamber body 1302 for maintaining a low-pressure environment. However, it will be appreciated that a plurality of CFD process stations 1300 may be included in a common process tool environment. For example, FIG. 4 depicts an embodiment of a multi-station processing tool 2400. Further, it will be appreciated that, in some embodiments, one or more hardware parameters of CFD process station 1300, including those discussed in detail below, may be adjusted programmatically by one or more computer controllers.

CFD process station 1300 fluidly communicates with reactant delivery system 1301 for delivering process gases to a distribution showerhead 1306. Reactant delivery system 1301 includes a mixing vessel 1304 for blending and/or conditioning process gases for delivery to showerhead 1306. One or more mixing vessel inlet valves 1320 may control introduction of process gases to mixing vessel 1304.

Some reactants, like BTBAS, may be stored in liquid form prior to vaporization at and subsequent delivery to the process station. For example, the embodiment of FIG. 3 includes a vaporization point 1303 for vaporizing liquid reactant to be supplied to mixing vessel 1304. In some embodiments, vaporization point 1303 may be a heated vaporizer. The saturated reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 1303 may be heat traced. In some examples, mixing vessel 1304 may also be heat traced. In one non-limiting example, piping downstream of vaporization point 1303 has an increasing temperature profile extending from approximately 100 degrees Celsius to approximately 150 degrees Celsius at mixing vessel 1304.

In some embodiments, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 1303. In one scenario, a liquid injector may be mounted directly to mixing vessel 1304. In another scenario, a liquid injector may be mounted directly to showerhead 1306.

In some embodiments, a liquid flow controller upstream of vaporization point 1303 may be provided for controlling a mass flow of liquid for vaporization and delivery to process station 1300. For example, the liquid flow controller (LFC) may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Showerhead 1306 distributes process gases toward substrate 1312. In the embodiment shown in FIG. 3, substrate 1312 is located beneath showerhead 1306, and is shown resting on a pedestal 1308. It will be appreciated that showerhead 1306 may have any suitable shape, and may have any suitable number and arrangement of ports for distributing processes gases to substrate 1312.

In some embodiments, a microvolume 1307 is located beneath showerhead 1306. Performing a CFD process in a microvolume rather than in the entire volume of a process station may reduce reactant exposure and sweep times, may reduce times for altering CFD process conditions (e.g., pressure, temperature, etc.), may limit an exposure of process station robotics to process gases, etc. Example microvolume sizes include, but are not limited to, volumes between 0.1 liter and 2 liters.

In some embodiments, pedestal 1308 may be raised or lowered to expose substrate 1312 to microvolume 1307 and/or to vary a volume of microvolume 1307. For example, in a substrate transfer phase, pedestal 1308 may be lowered to allow substrate 1312 to be loaded onto pedestal 1308. During a CFD process phase, pedestal 1308 may be raised to position substrate 1312 within microvolume 1307. In some embodiments, microvolume 1307 may completely enclose substrate 1312 as well as a portion of pedestal 1308 to create a region of high flow impedance during a CFD process.

Optionally, pedestal 1308 may be lowered and/or raised during portions the CFD process to modulate process pressure, reactant concentration, etc., within microvolume 1307. In one scenario where process chamber body 1302 remains at a base pressure during the CFD process, lowering pedestal 1308 may allow microvolume 1307 to be evacuated. Example ratios of microvolume to process chamber volume include, but are not limited to, volume ratios between 1:500 and 1:10. It will be appreciated that, in some embodiments, pedestal height may be adjusted programmatically by a suitable computer controller.

In another scenario, adjusting a height of pedestal 1308 may allow a plasma density to be varied during plasma activation and/or treatment cycles included in the CFD process. At the conclusion of the CFD process phase, pedestal 1308 may be lowered during another substrate transfer phase to allow removal of substrate 1312 from pedestal 1308.

While the example microvolume variations described herein refer to a height-adjustable pedestal, it will be appreciated that, in some embodiments, a position of showerhead 1306 may be adjusted relative to pedestal 1308 to vary a volume of microvolume 1307. Further, it will be appreciated that a vertical position of pedestal 1308 and/or showerhead 1306 may be varied by any suitable mechanism within the scope of the present disclosure. In some embodiments, pedestal 1308 may include a rotational axis for rotating an orientation of substrate 1312. It will be appreciated that, in some embodiments, one or more of these example adjustments may be performed programmatically by one or more suitable computer controllers.

Returning to the embodiment shown in FIG. 3, showerhead 1306 and pedestal 1308 electrically communicate with RF power supply 1314 and matching network 1316 for powering a plasma. In some embodiments, the plasma energy may be controlled by controlling one or more of a process station pressure, a gas concentration, an RF source power, an RF source frequency, and a plasma power pulse timing. For example, RF power supply 1314 and matching network 1316 may be operated at any suitable power to form a plasma having a desired composition of radical species. Examples of suitable powers are included above. Likewise, RF power supply 1314 may provide RF power of any suitable frequency. In some embodiments, RF power supply 1314 may be configured to control high- and low-frequency RF power sources independently of one another. Example low-frequency RF frequencies may include, but are not limited to, frequencies between 50 kHz and 500 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a CFD process recipe. In some cases, process recipe phases may be sequentially arranged, so that all instructions for a CFD process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In conventional deposition processes, plasma strikes last on the order of a few seconds or more in duration. In various implementations described herein, much shorter plasma strikes are applied during a CFD cycle. These may be on the order of 10 ms to 1 second, typically, about 20 to 80 ms, with 50 ms being a specific example. Such very short RF plasma strikes require extremely quick stabilization of the plasma. To accomplish this, the plasma generator may be configured such that the impedance match is set preset to a particular voltage, while the frequency is allowed to float. Conventionally, high-frequency plasmas are generated at an RF frequency at about 13.56 MHz. In various embodiments disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with CFD cycles. An example of such an embodiment is shown in the bottom row of Table 4, which is sometimes referred to as a “rapid ALD” process.

In some embodiments, pedestal 1308 may be temperature controlled via heater 1310. Further, in some embodiments, pressure control for CFD process station 1300 may be provided by butterfly valve 1318. As shown in the embodiment of FIG. 3, butterfly valve 1318 throttles a vacuum provided by a downstream vacuum pump (not shown). However, in some embodiments, pressure control of process station 1300 may also be adjusted by varying a flow rate of one or more gases introduced to CFD process station 1300.

As described above, one or more process stations may be included in a multi-station processing tool. FIG. 4 shows a schematic view of an embodiment of a multi-station processing tool 2400 with an inbound load lock 2402 and an outbound load lock 2404, either or both of which may comprise a remote plasma source. A robot 2406, at atmospheric pressure, is configured to move wafers from a cassette loaded through a pod 2408 into inbound load lock 2402 via an atmospheric port 2410. A wafer is placed by the robot 2406 on a pedestal 2412 in the inbound load lock 2402, the atmospheric port 2410 is closed, and the load lock is pumped down. Where the inbound load lock 2402 comprises a remote plasma source, the wafer may be exposed to a remote plasma treatment in the load lock prior to being introduced into a processing chamber 2414. Further, the wafer also may be heated in the inbound load lock 2402 as well, for example, to remove moisture and adsorbed gases. Next, a chamber transport port 2416 to processing chamber 2414 is opened, and another robot (not shown) places the wafer into the reactor on a pedestal of a first station shown in the reactor for processing. While the embodiment depicted in FIG. 4 includes load locks, it will be appreciated that, in some embodiments, direct entry of a wafer into a process station may be provided.

The depicted processing chamber 2414 comprises four process stations, numbered from 1 to 4 in the embodiment shown in FIG. 4. Each station has a heated pedestal (shown at 2418 for station 1), and gas line inlets. It will be appreciated that in some embodiments, each process station may have different or multiple purposes. For example, in some embodiments, a process station may be switchable between a CFD and PECVD process mode. Additionally or alternatively, in some embodiments, processing chamber 2414 may include one or more matched pairs of CFD and PECVD process stations. While the depicted processing chamber 2414 comprises four stations, it will be understood that a processing chamber according to the present disclosure may have any suitable number of stations. For example, in some embodiments, a processing chamber may have five or more stations, while in other embodiments a processing chamber may have three or fewer stations.

FIG. 4 also depicts an embodiment of a wafer handling system 2490 for transferring wafers within processing chamber 2414. In some embodiments, wafer handling system 2490 may transfer wafers between various process stations and/or between a process station and a load lock. It will be appreciated that any suitable wafer handling system may be employed. Non-limiting examples include wafer carousels and wafer handling robots. FIG. 4 also depicts an embodiment of a system controller 2450 employed to control process conditions and hardware states of process tool 2400. System controller 2450 may include one or more memory devices 2456, one or more mass storage devices 2454, and one or more processors 2452. Processor 2452 may include a CPU or computer, analog and/or digital input/output connections, stepper motor controller boards, etc.

In some embodiments, system controller 2450 controls all of the activities of process tool 2400. System controller 2450 executes system control software 2458 stored in mass storage device 2454, loaded into memory device 2456, and executed on processor 2452. System control software 2458 may include instructions for controlling the timing, mixture of gases, chamber and/or station pressure, chamber and/or station temperature, wafer temperature, target power levels, RF power levels, substrate pedestal, chuck and/or susceptor position, and other parameters of a particular process performed by process tool 2400. System control software 2458 may be configured in any suitable way. For example, various process tool component subroutines or control objects may be written to control operation of the process tool components necessary to carry out various process tool processes. System control software 2458 may be coded in any suitable computer readable programming language.

In some embodiments, system control software 2458 may include input/output control (IOC) sequencing instructions for controlling the various parameters described above. For example, each phase of a CFD process may include one or more instructions for execution by system controller 2450. The instructions for setting process conditions for a CFD process phase may be included in a corresponding CFD recipe phase. In some embodiments, the CFD recipe phases may be sequentially arranged, so that all instructions for a CFD process phase are executed concurrently with that process phase.

Other computer software and/or programs stored on mass storage device 2454 and/or memory device 2456 associated with system controller 2450 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 2418 and to control the spacing between the substrate and other parts of process tool 2400.

A process gas control program may include code for controlling gas composition and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with system controller 2450. The user interface may include a display screen, graphical software displays of the apparatus and/or process conditions, and user input devices such as pointing devices, keyboards, touch screens, microphones, etc.

In some embodiments, parameters adjusted by system controller 2450 may relate to process conditions. Non-limiting examples include process gas composition and flow rates, temperature, pressure, plasma conditions (such as RF bias power levels), pressure, temperature, etc. These parameters may be provided to the user in the form of a recipe, which may be entered utilizing the user interface.

Signals for monitoring the process may be provided by analog and/or digital input connections of system controller 2450 from various process tool sensors. The signals for controlling the process may be output on the analog and digital output connections of process tool 2400. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 2450 may provide program instructions for implementing the above-described deposition processes. The program instructions may control a variety of process parameters, such as DC power level, RF bias power level, pressure, temperature, etc. The instructions may control the parameters to operate in-situ deposition of film stacks according to various embodiments described herein.

The system controller will typically include one or more memory devices and one or more processors configured to execute the instructions so that the apparatus will perform a method in accordance with the present invention. Machine-readable media containing instructions for controlling process operations in accordance with the present invention may be coupled to the system controller.

An appropriate apparatus for performing the methods disclosed herein is further discussed and described in U.S. patent application Ser. Nos. 13/084,399, filed Apr. 11, 2011, and titled “PLASMA ACTIVATED CONFORMAL FILM DEPOSITION”; and 13/084,305, filed Apr. 11, 2011, and titled “SILICON NITRIDE FILMS AND METHODS,” each of which is incorporated herein in its entirety.

The apparatus/process described hereinabove may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically includes some or all of the following operations, each operation enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### Experimental

Experimental results show improved films resulting from the use of high chamber pressure and high RF power according to the disclosed embodiments. Table 3 below describes a particle performance comparison for deposition of silicon dioxide using BTBAS and O₂/N₂O for three processes.

TABLE 3

| | | | | | HF RF | | | Adder | Adder | Adder |
|---|---|---|---|---|---|---|---|---|---|---|
| | | | | HF RF | power | | | Count | Count | Count |
| | Si dose | | | power | (per | RF | | 0.12 | 0.16 | 0.2 |
| Process | time | | Pressure | (total) | station) | time | | microns | microns | microns |
| A | 1 | sec | 3.5 Torr | 2500 W | 625 W | 0.25 | | 11245 | 3709 | 1506 |
| B | 0.8 | s | 6 Torr | 2500 W | 625 W | 1 | s | 100 | 42 | 27 |
| C | 0.6 | s | 6 Torr | 4000 W | 1000 W | 0.25 | s | 58 | 16 | 7 |

Process A is a low pressure, low RF power process, Process B is a high pressure, low RF power process, and Process C is a high pressure, high RF power process. The Adder Count relates to the number of particles observed. It is preferable to observe fewer particles (i.e., a lower adder count is desirable). These results suggest that high pressure processes substantially reduce undesirable particle formation, and that high RF powers in combination with high pressures further improve this parameter.

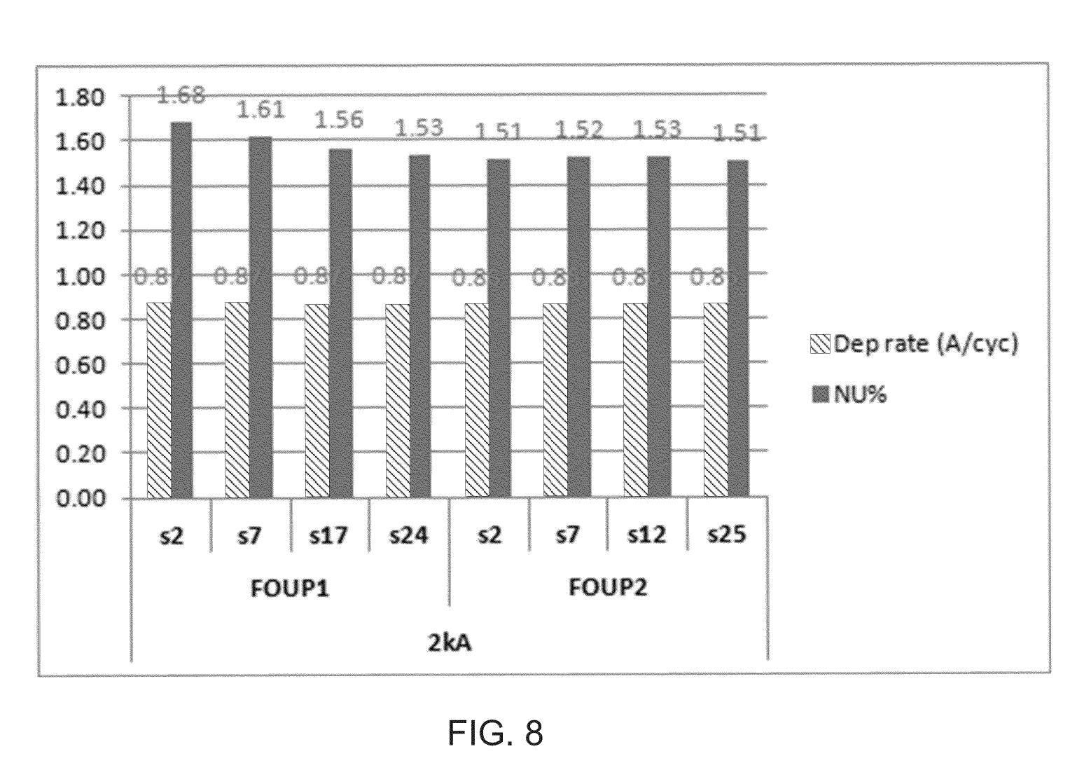

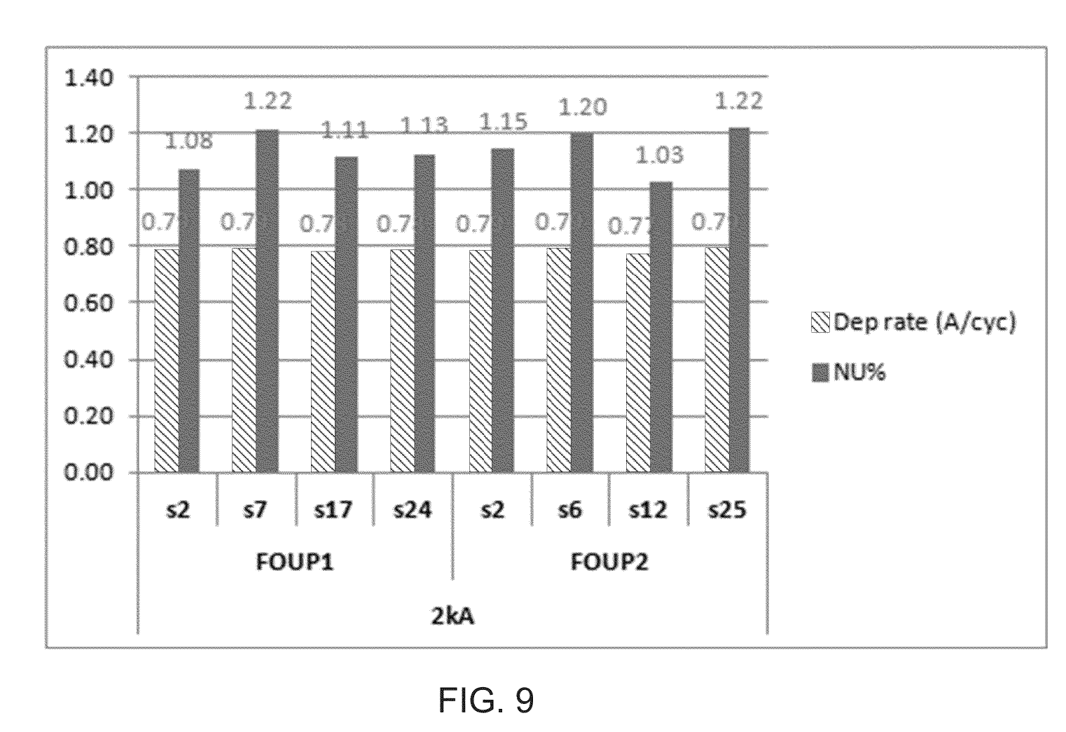

FIGS. 8 and 9 provide comparative data showing deposition rate and within-wafer percent non-uniformity for various substrates (e.g., s2, s7. etc.) having 2000 Å thick silicon dioxide films deposited thereon. Within-wafer non-uniformity is defined for the purposes of this disclosure as the (standard deviation of thickness measurements)/(mean of thickness measurements) for a particular substrate, and is expressed as a percentage. This is sometimes referred to as the “1-sigma” within wafer non-uniformity.

The data in FIG. 8 relate to a film formed at 6 Torr at 625 W/station (i.e., a high pressure, low RF power process). The deposition rate was fairly constant from wafer to wafer, and ranged from about 0.86-0.87 Å/cycle. The within-wafer non-uniformity was also fairly stable at about 1.51-1.68%.

The data in FIG. 9 relate to a film formed at 6 Torr and 1000 W/station (i.e., a high pressure, high RF power process). The deposition rate was constant from wafer to wafer at about 0.77-0.79 Å/cycle. The within-wafer non-uniformity was between about 1.03-1.22%, representing an improvement from the high pressure/low RF power film characterized in FIG. 8.

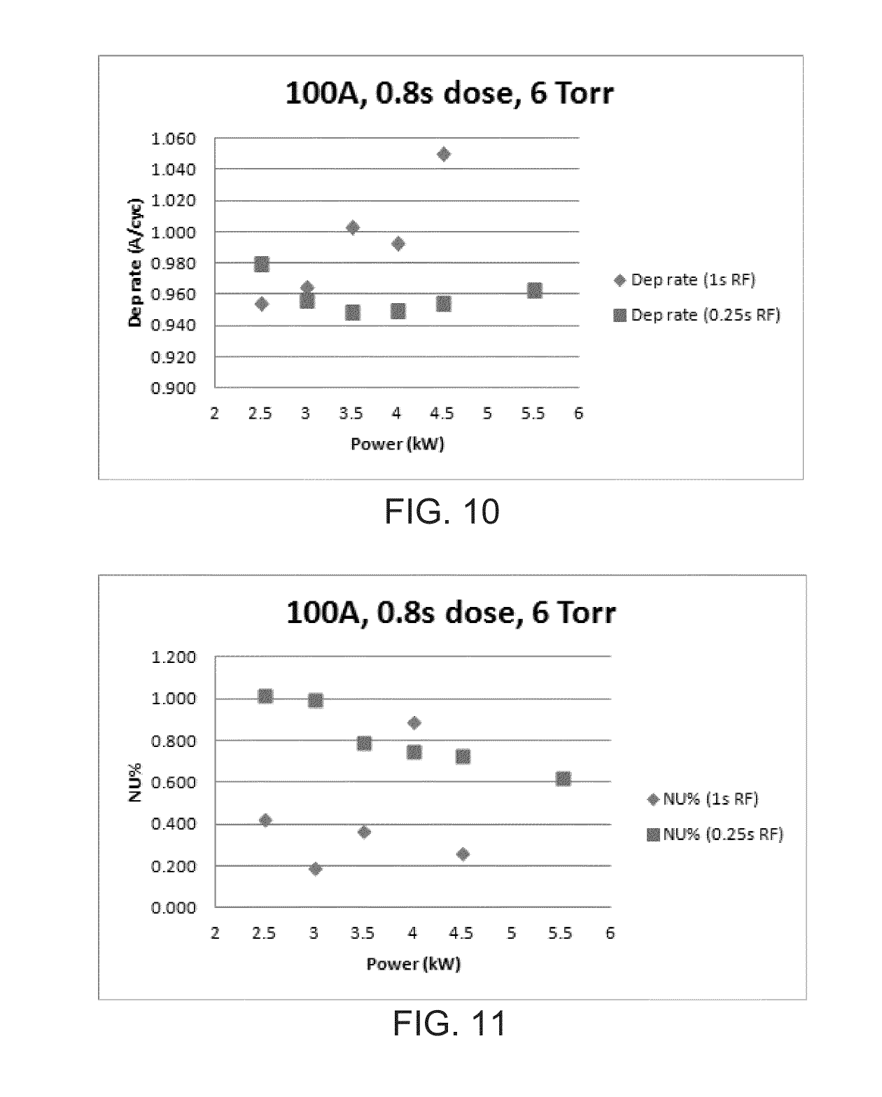

FIGS. 10 and 11 show the deposition rate (FIG. 10) and non-uniformity (FIG. 11) for 100 Å thick silicon dioxide films deposited at 6 Torr, using a silicon-containing precursor dose time of 0.8 s, for various RF powers and durations. In these figures, the power is recited in terms of the power delivered to four stations. In other words, the per station power is calculated by dividing the recited power levels by 4. With regard to FIG. 10, the deposition rate for the longer RF time is more sensitive to the increased RF power levels. With regard to FIG. 11, higher RF times result in a lower non-uniformity as compared to the shorter RF time (except in the 4 kW case). Without being bound by a particular theory, it is believed that this result may arise due to profile inversion from edge-thick to edge-thin behavior. For the 0.25 s RF exposure time, in order to achieve a non-uniformity of less than 0.7% for a 100 Å film, an RF power of at least 4 kW (1 kW/station) should be used.

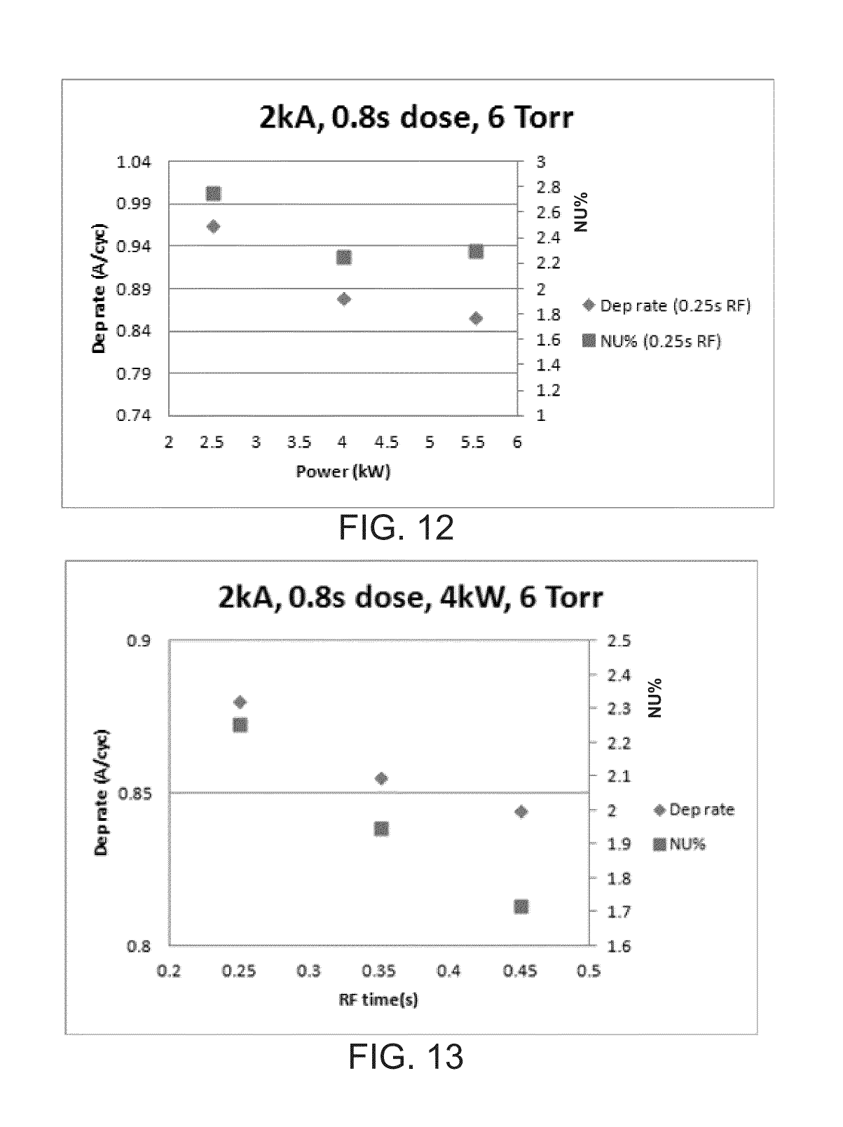

FIG. 12 shows the deposition rate and non-uniformity for a 2000 Å thick silicon dioxide film formed at 6 Torr and various power levels. The RF exposure time in this case was 0.25 s, and the silicon-containing reactant was introduced for a period of 0.8 s.

FIG. 13 shows the deposition rate and non-uniformity for a 2000 Å thick silicon dioxide film formed at 6 Torr, 1000 W/station (4 kW total) (a high pressure, high RF power process), for various RF exposure times. The silicon-containing reactant was introduced for a period of 0.8 s.

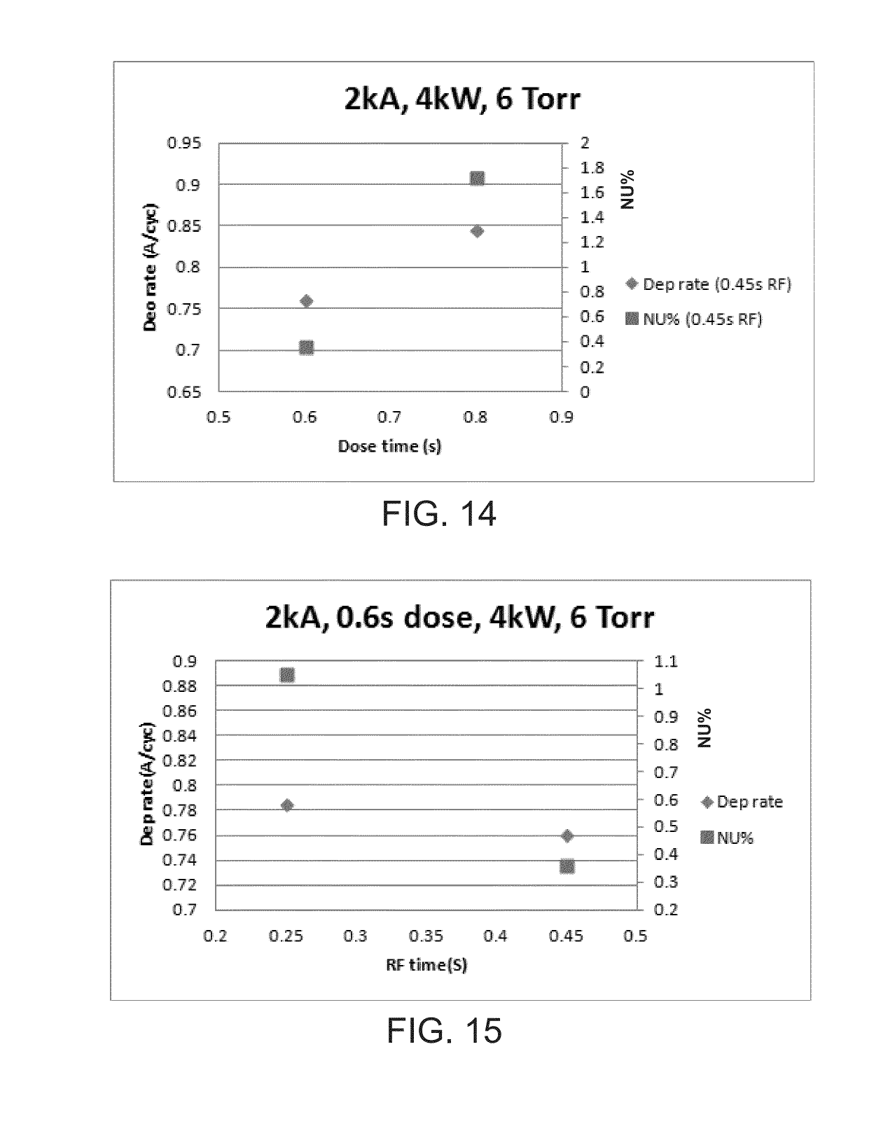

FIG. 14 shows the deposition rate and non-uniformity for a 2000 Å thick silicon dioxide film formed at 6 Torr, 1000 W/station (4 kW total) for different silicon-containing reactant dose times. The lower dose time resulted in a lower deposition rate and a lower non-uniformity. The decrease in non-uniformity was especially substantial. Without wishing to be bound by a particular theory, it is believed that this improvement in non-uniformity may relate to an increased purge efficiency and removal of excess precursor from the chamber at the lower Si dose times. With longer Si dose times, the residence of excess material may result in parasitic PECVD reactions during the RF strike, thus increasing the non-uniformity. The lower Si dose time may result in better purge efficiency and therefore a lower likelihood of parasitic PECVD reactions.

FIG. 15 shows the deposition rate and non-uniformity for a 2000 Å thick silicon dioxide film deposited at 6 Torr, 1000 W/station (4 kW total), with a silicon-containing reactant dose time of 0.6 s, for two different RF exposure times. In this case, the longer RF exposure time results in a slightly decreased deposition rate and a substantially decreased non-uniformity.

One advantage of the disclosed embodiments is that wafer throughput can be increased. For example, wafer throughput was increased by about 50% using 0.25 s RF/0.6 s Si dose/1000 W/station/6 Torr, as compared to a process using 1 s RF/0.8 s Si dose/625 W/station/6 Torr, The higher power process also showed increased particle performance and a lower non-uniformity than the lower power process. The increase in throughput may be further increased to about 64% when an RF exposure time of about 0.15 s is used. This film showed a non-uniformity of about 1.5%. Additional data related to process cycle times is presented in Table 4 below.

Table 4 shows process data for films deposited at various pressures and RF power levels.

TABLE 4

| | | | Cycle | | | |
|---|---|---|---|---|---|---|
| | Pressure | Power | Time | NU | | Dep. Rate |
| Hardware | (Torr) | (W/station) | (ms) | (%) | RI | (Å/cycle) |
| Version 1 | 3.5 | 625 | 1990 | 1.5 | 1.47 | 0.85 |
| Version 2 | 3.5 | 625 | 1990 | 1.38 | 1.47 | 0.87 |
| Version 2 | 6 | 1000 | 940 | 1.5 | 1.46 | 0.82 |
| Version 2 | 6 | 1500 | 250 | 0.92 | 1.47 | 0.75 |

The data in Table 4 show that the high pressure, high RF power deposition process allows cycle times to be substantially reduced. The data were collected on two different versions of hardware. The version 2 hardware included point of use valve manifold hardware, which is further discussed and described in U.S. patent application Ser. No. 13/626,717, filed Sep. 25, 2012, and titled, “POINT OF USE VALVE MANIFOLD FOR SEMICONDUCTOR FABRICATION EQUIPMENT,” which is herein incorporated by reference in its entirety.

In various embodiments, the RF exposure time and/or silicon-containing reactant dose times will be lower than the times recited in the figures. For example, in some cases the RF exposure time is less than about 250 ms, for example less than about 50 ms. The silicon-containing reactant exposure may have a duration of less than about 100 ms, for example less than about 60 ms. The high pressure/high RF power regime helps minimize these times while producing high quality films.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated may be performed in the sequence illustrated, in other sequences, in parallel, or in some cases omitted. Likewise, the order of the above-described processes may be changed.

The subject matter of the present disclosure includes all novel and nonobvious combinations and subcombinations of the various processes, systems and configurations, and other features, functions, acts, and/or properties disclosed herein, as well as any and all equivalents thereof.

1. A method of depositing a film on a substrate surface in a single or multi-station reaction chamber, the method comprising:
(a) introducing a first reactant in vapor phase into the reaction chamber under conditions allowing the first reactant to adsorb onto the substrate surface;
(b) introducing a second reactant in vapor phase into the reaction chamber under conditions allowing the second reactant to adsorb onto the substrate surface; and
(c) periodically exposing the substrate surface to plasma when the vapor phase flow of the first reactant has ceased in order to drive a surface reaction between the first and second reactants on the substrate surface to form the film, wherein a radio frequency (RF) power used to drive formation of the plasma is greater than about 1.1 Watts per station per square centimeter of substrate area, and wherein a pressure in the reaction chamber during operations (a)-(c) is greater than 4 Torr.

2. The method of claim 1, further comprising purging the reaction chamber immediately before exposing the substrate surface to plasma.

3. The method of claim 1, further comprising purging the reaction chamber immediately after exposing the substrate surface to plasma.

4. The method of claim 1, wherein the RF power used to drive formation of the plasma is greater than about 1.4 Watts per station per square centimeter of substrate area.

5. The method of claim 4, wherein the RF power used to drive formation of the plasma is between about 1.4-4.2 Watts per station per square centimeter of substrate area.

6. The method of claim 1, wherein the pressure in the reaction chamber is less than about 20 Torr.

7. The method of claim 6, wherein the pressure in the reaction chamber is between about 5-10 Torr.

8. The method of claim 1, wherein the first reactant is a silicon-containing reactant.

9. The method of claim 8, wherein the second reactant is an oxygen-containing reactant.

10. The method of claim 8, wherein the second reactant is a nitrogen-containing reactant.

11. The method of claim 8, wherein the silicon-containing reactant is introduced into the reaction chamber during a pulse having a duration of less than about 50 ms.

12. The method of claim 1, wherein the first reactant is a metal-containing reactant.

13. The method of claim 12, wherein the second reactant is an oxygen-containing reactant.

14. The method of claim 12, wherein the second reactant is a nitrogen-containing reactant.

15. The method of claim 1, wherein the film formed on the substrate has a within wafer non-uniformity of less than about 1.5%.

16. The method of claim 15, wherein the film formed on the substrate has a within wafer non-uniformity of less than about 0.5%

17. The method of claim 1, wherein plasma is exposed to the substrate surface in operation (d) for a period of less than about 250 ms.

18. A method of depositing a film on a substrate surface, the method comprising:
(a) introducing a first reactant in vapor phase into the reaction chamber under conditions allowing the first reactant to adsorb onto the substrate surface;
(b) introducing a second reactant in vapor phase into the reaction chamber under conditions allowing the second reactant to adsorb onto the substrate surface; and
(c) periodically exposing the substrate surface to plasma when the vapor phase flow of the first reactant has ceased in order to drive a surface reaction between the first and second reactants on the substrate surface to form the film, wherein a pressure in the reaction chamber during operations (a)-(c) is between about 5-10 Torr.

19. (canceled)

20. An apparatus for depositing films on a substrate, the apparatus comprising:
a reaction chamber;
an inlet port for delivering gas phase reactants to the reaction chamber;
a plasma generator for providing plasma to the reaction chamber; and
a controller comprising instructions for
(a) introducing a first reactant in vapor phase into the reaction chamber;
(b) introducing a second reactant in vapor phase into the reaction chamber;
(c) periodically striking a plasma to expose the substrate surface to plasma when the vapor phase flow of the first reactant has ceased in order to drive a surface reaction between the first and second reactants on the substrate surface to form the film;
(d) maintaining a pressure in the reaction chamber at greater than 4 Torr; and
(e) applying an RF power greater than about 1.1 Watts per station per square centimeter of substrate area to drive formation of the plasma.

21-28. (canceled)
